(19) United States
(12) Patent Application Publication
(10) Pub. No.: US 2007/0069929 A1
(43) Pub. Date: Mar. 29, 2007

(54) High speed sigma delta device

(75) Inventor: Andrew Martin Mallinson, Kelowna (CA)

Correspondence Address: STEVENS LAW GROUP, P.O. BOX 1667, SAN JOSE, CA, 95109, US

(73) Assignee: ESS Technology, Inc., Fremont, CA (US)

(21) Appl. No.: 11/238,426

(22) Filed: Sep. 28, 2005

(51) Int. Cl. H03M 3/00

(52) U.S. Cl. 341/143

(57) ABSTRACT

A system and method are provided for a high speed sigma delta circuit operation including a sigma-delta analog to digital converter configured to receive an input signal and to output a single digital bit representative of that signal and any associated noise. Further included is a finite impulse response filter configured to accumulate a stream of digital bits from the ADC device within a shift register, to sum a coefficient of each bit, and weigh each bit in response to a corresponding bit in the shift register. Also included is a quantizing device for receiving the summation of the weighted bits of the FIR device and rendering a representative bit as output.

### BACKGROUND

Numerous examples of data dependant scrambling in a sigma delta device are documented in the literature. The basic idea is to ensure that the errors in the analog to digital converters (ADCs) get scrambled or moved to higher frequency. In conventional devices, many methods exist that attempt to isolate errors existing in a data signal and to somehow remove the errors from the signal, and perhaps move them to a frequency outside the frequency of the digital signal. In most systems, however, such error removal fails at high speeds.

Therefore, there exists a need in the art for improved error reduction in ADCs, and, as will be seen, the invention accomplishes this in an elegant manner.

### DETAILED DESCRIPTION

In one embodiment, a circuit is provided as a sigma-delta ADC device configured to receive an input signal and outputting a single digital bit representative of that that signal possibly with addition noise. The circuit includes a finite impulse response filter accepting the stream of digital bits from the ADC device, accumulating those bits within a shift register and summing a coefficient of each bit multiplied by −1 or 1 dependant upon the corresponding bit in the shift register. The circuit further comprises a quantizing device accepting as input the summation of the weighted bits of the FIR device and rendering a single bit as output.

The value of the coefficients of the FIR device are determined such the frequency response of the FIR filter is, in addition to possibly other desirable frequency domain shaping, at least also an equalization filter for the purpose of removing dispersion present in the input to the ADC device, thereby, in conjunction with the quantizing device, rendering an output bit stream substantially free from dispersion. The quantizing device, in one embodiment, can be a comparator, or a slicer. A “Slicer” is commonly used in a data read channel application for slicing through a data signal with a DC level and reporting a “1” if above the DC level or a “0” if below the DC level. In usual terminology, this component is a comparator set at some point between a high level and a low level of the incoming equalized analog signal, turning it into a digital single bit.

A system and method are provided to enable a read channel using a sigma delta device. A “read channel” is characterized by a means to impose a frequency domain shaping (a so called “equalization” filter) on a signal prior to its quantization into a single digital bit. The frequency domain shaping is typically implemented to compensate for an undesirable time domain distortion or dispersion of the signal. This renders a single bit with minimum disturbance of relative timing for further downstream processing, for example in a data recovery circuit. The invention provides a sigma delta loop operating on the input signal at a high speed to create a stream of binary bits that represent the input signal plus random noise in a predictable frequency band (“noise shaped” quantization noise). The circuit includes a semi-analog FIR filter accepting the stream of binary bits input to a shift register to create, in the analog domain, the weighted sum of the bits held in the shift register. The novel FIR filter performs two functions: to filter the shaped quantization noise and to implement the equalization filter. The value of the coefficients of the FIR device are determined such that the frequency response of the FIR filter performs the desirable frequency domain shaping and equalization filtering to remove dispersion present in the input to the ADC device. Thus, in conjunction with the quantizing device, the process renders an output bit stream substantially free from dispersion. Therefore, the output of this semi-analog FIR filter may be quantized into a single bit, this bit being the desired post-equalization bit to be fed to further downstream read channel processing

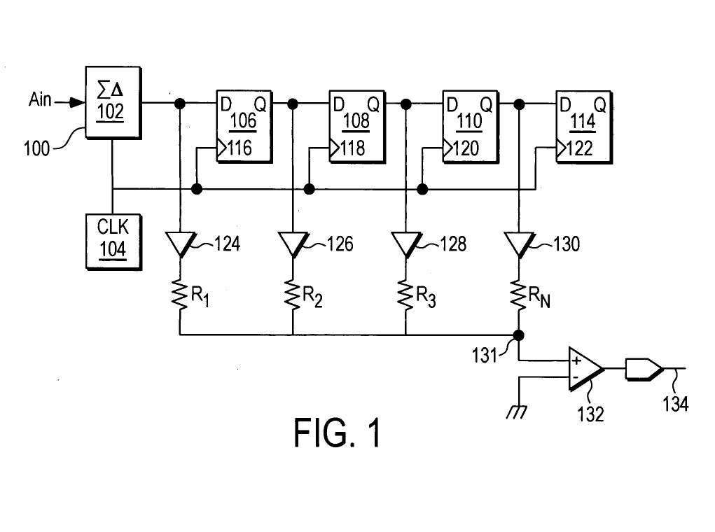

Referring to FIG. 1, a system configured as a semi-analog equalizer for a read channel 100 is illustrated. The system is configured to receive an analog input signal Ain at sigma-delta converter 102, which outputs a stream of logic 0's and 1's for further processing. The converter 102 is clocked by clocking source 104, which also clocks delay elements 106, 108, 110 and 114 at clock inputs 116, 118, 120 and 122 respectively. The delay elements are illustrated here as flip-flops, but could be other well known delay elements. The first element 106 receives an output signal from converter 102 in its D input, then outputs its Q output according to the clock signal received from clock source 104. The Q output is received at the D input of delay device 108, where the delay device 108 outputs its Q output to the D input of delay device 114. This series of delay devices can be numerous, such as 64 for a 64 element FIR filter.

The D input for each delay device is output to a voltage driver or buffer 124, 126, 128 and 130 as well as a resistor R1, R2, R3 . . . Rn respectively. The ends of the each resistor are tied together at node 131, and input to comparator 132, as shown to the positive input. The negative input is grounded. The output 134 is a digital output, and a digital signal that represents digital data is thereby derived.

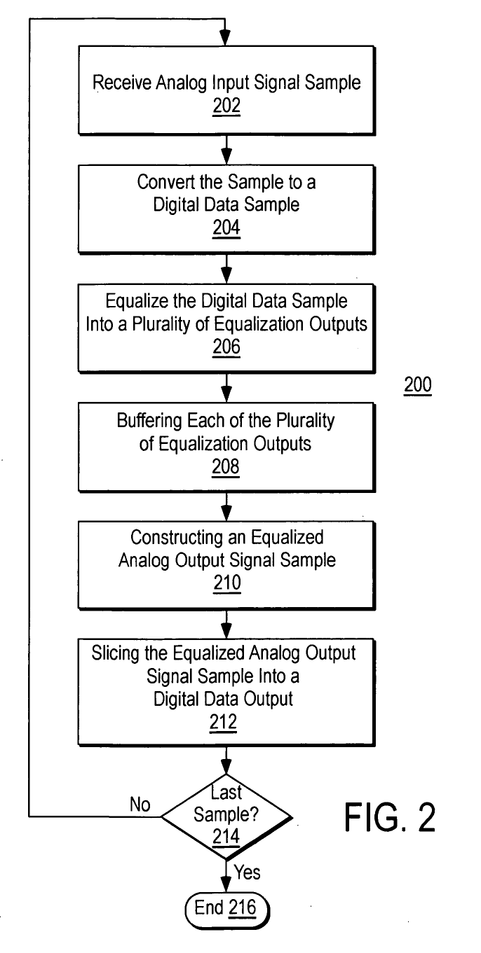

Referring to FIG. 2, a flow chart illustrating the operation of the circuit of FIG. 1 is illustrated. In step 202, an analog input signal sample is received for conversion from an analog signal to digital data. In step 204, the sample is converted into a digital data sample with sigma delta converter 102 (FIG. 1). In step 206, the digital data sample is delayed in a plurality of delay elements, such as the output from the D inputs of each delay element of FIG. 1. In step 208, each of the delayed outputs is buffered with buffering units 124, 126, 128 and 130 (FIG. 1). An equalized output signal is then constructed in step 210. This equalized output is then sliced into a digital data output 212 with the slicing comparator 132 (FIG. 1). In step 214, it is queried whether there is another sample. If there is, the process returns to step 202 to begin processing the new sample. If not, then the process ends at step 216.

It will be understood by those skilled in the art that any convenient means to implement a semi-analog FIR filter can be used. For example, the delay elements as shown in FIG. 1 may connect to current sources and operate a current switch to enable the current to add to the output, or to reverse the sense of the current before addition to the output. Indeed any means to make the analog weighed sum of the delay values can be used to implement the semi-analog FIR.

The invention has been described in the context of a high speed sigma delta device and related method of operation. Those skilled in the art, however, will understand that the invention has broader utility, which is defined by the appended claims and their equivalents.

1. A circuit comprising:
a sigma-delta analog to digital converter (ADC) configured to receive an input signal and outputting a digital representation of that signal and any associated noise;
a finite impulse response (FR) filter configured to accumulate a stream of digital bits from the ADC, to sum a coefficient of each bit, and to combine each bit in response to a corresponding bit;
a quantizing device configured to receive the combined bits of the FIR filter and to render a representative digital output.

2. A circuit according to claim 1, wherein the wherein the FIR filter is configured to weigh individual information bits of the digital representation.

3. A circuit according to claim 1, wherein the wherein the FIR filter is configured with a shift register to accumulate a stream of digital bits and to combine individual bits on the stream of digital bits in a shift register.

4. A circuit according to claim 3, wherein the wherein the FIR filter is configured to weigh individual information bits of the digital representation based on a factor that depends upon the corresponding bit in the shift register.

5. A circuit comprising:
a sigma-delta analog to digital converter (ADC) device configured to receive an input signal and outputting a digital representative of that the input signal and addition noise if any exists;
a finite impulse response (FIR)filter receiving the stream of digital bits from the ADC device into a shift register, accumulating those bits within a shift register and summing a coefficient of each bit multiplied by a factor dependant upon the corresponding bit in the shift register;
a quantizing device accepting as input the summation of the weighted bits of the FIR device and rendering a single bit as output.

6. A circuit according to claim 5, wherein the value of the coefficients of the FIR filter device are determined such the frequency response of the FIR filter is, in addition to possibly other desirable frequency domain shaping, at least also an equalization filter for the purpose of removing dispersion present in the input to the ADC device, thereby, in conjunction with the quantizing device, rendering an output bit stream substantially free from dispersion.

7. A data equalization circuit, comprising
a sigma-delta modulator configured to receive an analog input signal and convert it into a digital data stream according to a clock signal driving the sigma delta modulator;
a finite impulse response (FIR) filter configured to filter the digital data stream to produce a digitally filtered signal that is an equalized representation of the analog input signal; and,
a slicing circuit configured to derive a digital data output from the digitally filtered signal.

8. A circuit accord to claim 7, wherein the sigma delta modulator is configured to produce a stream of digital data values; wherein the FIR filter is configured to receive the stream of digital and to generate a digitally filtered signal that is an equalized representation of the analog input signal; and wherein the slicing circuit is configured to derive samples from the digitally filtered signal to produce a digital data output with reduced dispersion.

9. A circuit according to claim 7, wherein the FIR filter includes a series of delay elements that are each driven by common clock, when a first element is configured to receive and output signal having digital values from the sigma delta modulator, a second element is configured to receive an output from the first element, and subsequent elements in the series are similarly configured to receive outputs from an element occurring earlier in the series of delay elements.

10. A circuit according to claim 7, wherein the FIR filter has a series of delay elements each configured to output a plurality of signals through individual voltage buffers and individual resistor values to generate an weighted analog signal, and where in the slicing circuit includes a comparison circuit configured to derive a digital data signal from the equalized analog signal.

11. A circuit according to claim 7, wherein the wherein the FIR filter is configured to weigh individual information bits of the digital representation.

12. A circuit according to claim 7, wherein the wherein the FIR filter is configured with a shift register to accumulate a stream of digital bits and to combine individual bits on the stream of digital bits in a shift register.

13. A circuit according to claim 12, wherein the wherein the FIR filter is configured to weigh individual information bits of the digital representation based on a factor that depends upon the corresponding bit in the shift register.
